(19) United States
(12) Patent Application Publication
(10) Pub. No.: US 2012/0026702 A1
(43) Pub. Date: Feb. 2, 2012

(54) Electronic Apparatus

(76) Inventor: Takahiro Sugai, Kokubunji-shi (JP)

(21) Appl. No.: 13/016,618

(22) Filed: Jan. 28, 2011

(30) Foreign Application Priority Data
Jul. 28, 2010 (JP) 2010-169633

(51) Int. Cl. H05K 5/00

(52) U.S. Cl. 361/752

(57) ABSTRACT

According to one embodiment, there is provided an electronic apparatus, including: an electrically-insulative housing having a first part and a second part attachable to and detachable from the first part; a circuit board housed in the housing; a signal wire formed on an inner face of the second part; and a connector formed to electrically connect the signal wire and a terminal part of the circuit board.

### CROSS-REFERENCE TO RELATED APPLICATION(S)

This application is based upon and claims the benefit of priority from Japanese Patent Application No. 2010-169633, filed on Jul. 28, 2010, the entire contents of which are incorporated herein by reference.

### FIELD

Embodiments described herein relate generally to an electronic apparatus in which a part of a housing, provided with wiring, is attachable and detachable.

### BACKGROUND

Generally, it is preferable that an electronic apparatus such as a portable computer is formed to with a thin and compact housing that serves as an outline of the apparatus, in view of a portability.

As a thin housing, for example, JP-2005-268521-A discloses an electronic apparatus in which, a wiring pattern is integrally formed on an inner face of the housing by printing a conductive adhesive, and a circuit component such as a connector is bonded to a land part of this wiring pattern.

In such structure, the conductive adhesive for forming the wiring pattern is utilized to electrically connect the wiring pattern and circuit component, thereby reducing the number of cables etc., and reducing the housing in size to save space.

In JP-2005-268521-A, the circuit component is directly bonded to the inner face of the housing. In such a structure, for example, when deflection occurs in the housing due to an external force, a stress is produced in a bonded part between the circuit component and wiring pattern, which might lead to destruction or damage of the bonded part.

However, in the structure in which the circuit component is directly bonded to the inner face of the housing, the entire housing has to be replaced upon occurrence of trouble in the bonded part, thus requiring much time and effort for repair.

### BRIEF DESCRIPTION OF THE DRAWINGS

A general architecture that implements the various feature of the present invention will now be described with reference to the drawings. The drawings and the associated descriptions are provided to illustrate embodiments of the present invention and not to limit the scope of the present invention.

FIG. 1 illustrates a portable computer according to an embodiment.

FIG. 2 explodedly illustrates a positional relationship between: a unit structure of a housing provided with plural signal wires and plural adhesive-filled parts; and a connector having connection terminals.

FIG. 3 cross-sectionally illustrates a state in which the connector is bonded to a connector-mounting region of the housing via conductive adhesives.

FIG. 4 cross-sectionally illustrates a positional relationship between: the housing provided with the signal wires and adhesive-filled parts; and the connector.

FIG. 5 cross-sectionally illustrates a state in which the signal wires provided in the housing and a printed circuit board are electrically connected to each other via a rubber connector.

FIG. 6 is a cross-sectional view taken along the line F6-F6 of FIG. 5.

FIG. 7 cross-sectionally illustrates a state before pressure is applied to the rubber connector between the printed circuit board and a bottom wall of the housing.

### DETAILED DESCRIPTION

In general, according to one embodiment, there is provided an electronic apparatus, including: an electrically-insulative housing having a first part and a second part attachable to and detachable from the first part; a circuit board housed in the housing; a signal wire formed on an inner face of the second part; and a connector formed to electrically connect the signal wire and a terminal part of the circuit board.

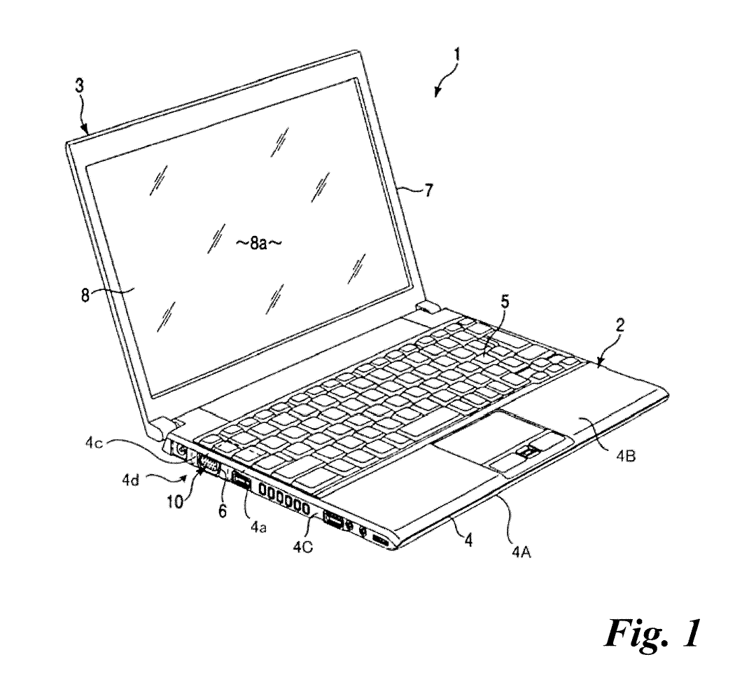

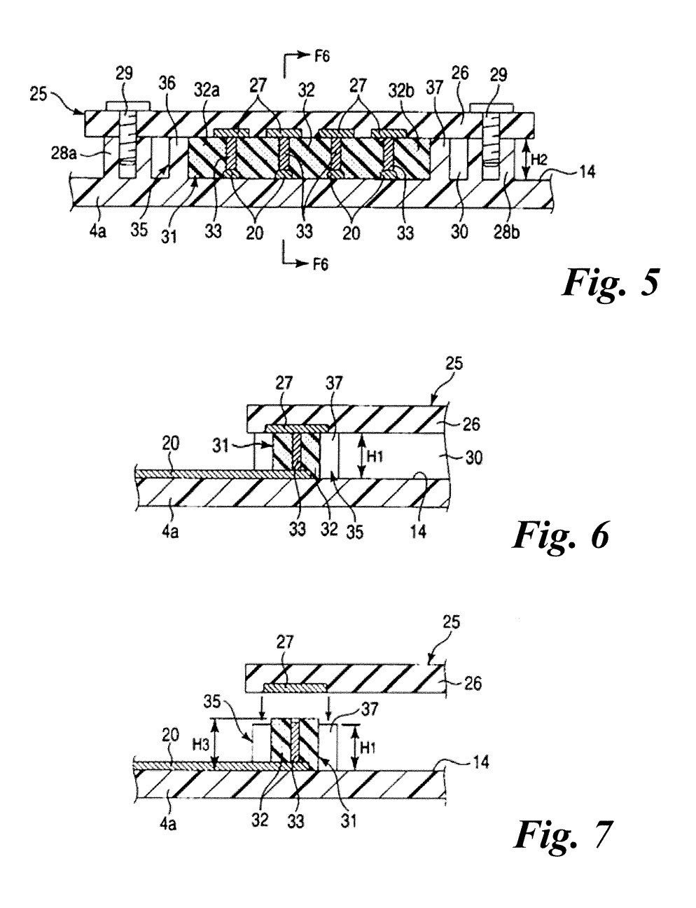

Hereinafter, an embodiment will be described with reference to FIGS. 1 to 7.

FIG. 1 illustrates a portable computer 1 serving as an example of an electronic apparatus. The portable computer 1 includes a computer main body 2 and a display module 3.

The computer main body 2 includes a housing 4. The housing 4 is formed by using a synthetic resin material, for example, thus providing an electrical insulating property. The housing 4 is formed into a flat box-like shape having an upper wall 4B and a lateral wall 4C. The upper wall 4B of the housing 4 supports a keyboard 5. The lateral wall 4C rises from a lateral edge of a bottom wall 4A. The lateral wall 4C of the housing 4 is provided with a rectangular opening 6.

The bottom wall 4A includes two parts, and is formed so as to be separable. A part of the bottom wall 4A (i.e., a bottom wall 4a) is formed as a separate body attachable to and detachable from the bottom wall 4A. The lateral wall 4C also includes two parts, and is formed so as to be separable. A part of the lateral wall 4C (i.e., a lateral wall 4c) is formed as a separate body attachable to and detachable from the lateral wall 4C.

The opening 6 is provided in the lateral wall 4c attachable to and detachable from the lateral wall 4C. The lateral wall 4c having this opening 6 and the bottom wall 4a attachable to and detachable from the bottom wall 4A are integrated with each other. Hereinafter, a structure in which the lateral wall 4c and the bottom wall 4a are integrated with each other will be referred to as a “unit structure 4d”.

As illustrated in FIG. 1, the display module 3 includes: a display housing 7; and a liquid crystal display panel 8 contained in the display housing 7. The display housing 7 is formed into a flat box-like shape having a size substantially equal to that of the computer main body 2. The liquid crystal display panel 8 has a screen 8a on which image information and/or character information are/is displayed.

The screen 8a is exposed to outside of the display housing 7 through a front face of the display housing 7.

The display module 3 is supported at a rear end portion of the computer main body 2 via unillustrated hinges. Therefore, the display module 3 is rotatable between: a closed position at which the display module 3 lies on the computer main body 2 so as to cover the keyboard 5; and an opened position at which the display module 3 rises from the rear end portion of the computer main body 2 so as to expose the keyboard 5 and the screen 8a.

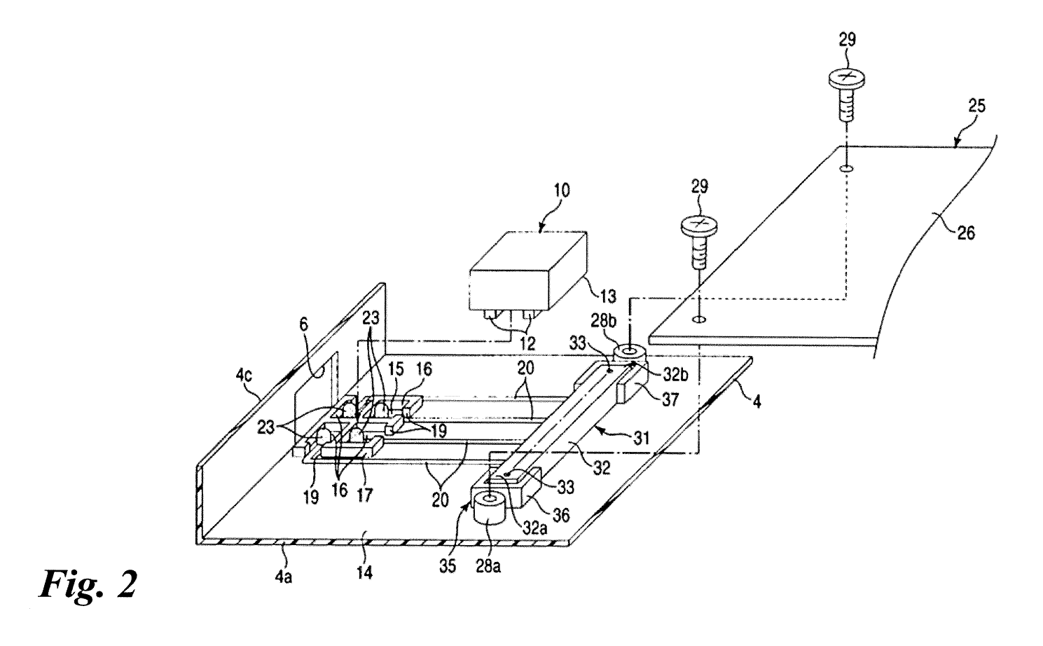

As illustrated in FIGS. 1 and 2, a connector 10 is located inside the opening 6 of the lateral wall 4c. The connector 10 serves to establish a connection with a peripheral device (not illustrated) such as an external monitor, for example. The connector 10 has plural connection terminals 12. The connection terminals 12 are arranged in a matrix on a flat lower face 13 of the connector 10.

The connector 10 is supported over an inner face 14 of the bottom wall 4a of the unit structure 4d. The inner face 14 of the unit structure 4d has a connector-mounting region 15. The connector-mounting region 15 is a region through which the connector 10 is fixed to the bottom wall 4a of the unit structure 4d and which is located adjacent to the opening 6.

As illustrated in FIG. 2, the lateral wall 4c serving as a part of the lateral wall 4C and the bottom wall 4a serving as a part of the bottom wall 4A constitute the unit structure 4d attachable to and detachable from the lateral wall 4C and the bottom wall 4A. For example, the unit structure 4d may be attachable to and detachable from housing (the lateral wall 4C and the bottom wall 4A) via a latch structure (not illustrated) or the like.

As illustrated in FIGS. 2 to 4, plural adhesive-filled parts 16 are provided in the connector-mounting region 15. The adhesive-filled parts 16 are partitioned into a grid pattern by a dividing wall 17 so as to conform to the connection terminals 12 of the connector 10. The dividing wall 17 has a rib shape protruded toward an inner region of the housing 4 from the inner face 14 of the bottom wall 4a, and surrounds each adhesive-filled part 16. Each adhesive-filled part 16 is opened upward from the bottom wall 4a, and has a shape larger than that of each connection terminal 12 of the connector 10.

The dividing wall 17 includes plural wire introduction parts 19. The wire introduction parts 19 each have a slit shape opened to the associated adhesive-filled part 16. At positions corresponding to the wire introduction parts 19, the inner face 14 of the bottom wall 4a is exposed.

As illustrated in FIG. 2, the inner face 14 of the bottom wall 4a is integrally provided with plural signal wires 20. A conductive adhesive is applied to the inner face 14 of the bottom wall 4a in the form of a line, thereby forming each signal wire 20. The signal wires 20 are extended in a width direction of the housing 4, and are arranged in parallel at intervals. As a method for applying a conductive adhesive to the inner face 14 of the bottom wall 4a, a screen printing method or a dispense method, for example, may be used.

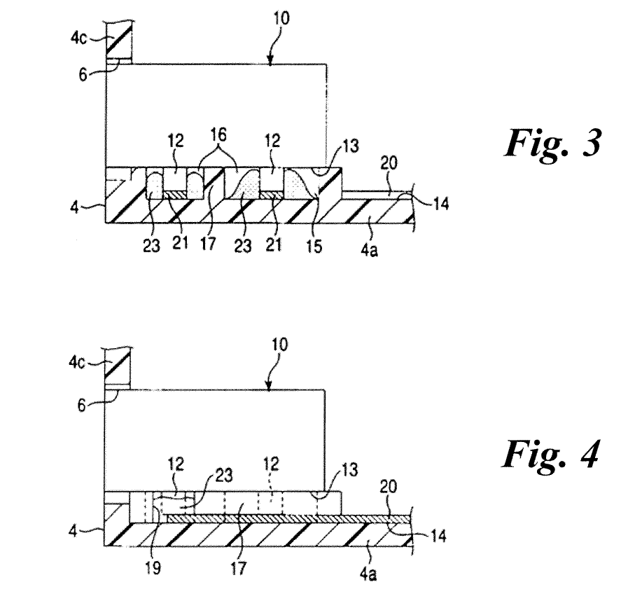

One end of each signal wire 20 is inserted into the associated adhesive-filled part 16 through the wire introduction part 19 of the dividing wall 17. One end of each signal wire 20 is provided with a land 21 such as one illustrated in FIG. 3. The land 21 is located at the bottom of each adhesive-filled part 16.

As illustrated in FIGS. 3 and 4, the connector 10 is superposed on the dividing wall 17. The lower face 13 of the connector 10 closes open ends of the adhesive-filled parts 16 from above. Thus, the connection terminals 12 of the connector 10 are inserted into the adhesive-filled parts 16, and are stacked over the lands 21.

The adhesive-filled parts 16 are filled with conductive adhesives 23. The conductive adhesives 23 are hardened with the connection terminals 12 and the lands 21 covered by the conductive adhesives 23 in an integrated manner. The conductive adhesives 23 filled into the adjacent adhesive-filled parts 16 are maintained in a state where the conductive adhesives 23 are electrically insulated by the dividing wall 17.

Consequently, the connector 10 is maintained in a state where the connector 10 is fixed onto the connector-mounting region 15 of the unit structure 4d via the conductive adhesives 23, and the connection terminals 12 of the connector are electrically connected to the lands 21 of the signal wires 20.

As illustrated in FIG. 2, the other ends of the signal wires 20, which are located opposite to the lands 21, are guided in a direction away from the connector-mounting region 15, and are arranged in a row at intervals on the inner face 14 of the bottom wall 4a.

The unit structure 4d formed as described above is fitted to the bottom wall 4A and the lateral wall 4C, thereby forming the housing 4. A printed circuit board 25 is contained inside the housing 4. As illustrated in FIG. 5, the printed circuit board 25 has: a circuit board 26; and plural pads 27 formed at one end of a lower face of the circuit board 26. The pads 27 are exemplified as terminal parts brought into electrical conduction with a conductor pattern of the printed circuit board 25, and are arranged in a row at intervals so as to be associated with the other ends of the signal wires 20.

One end of the circuit board 26 is fixed onto a pair of boss parts 28a and 28b, protruded from the inner face 14 of the bottom wall 4a, via screws 29 serving as fixtures. Therefore, the circuit board 26 is located in parallel with the inner face 14 of the bottom wall 4a, and a gap 30 having a height equivalent to that of each of the boss parts 28a and 28b is provided between the circuit board 26 and the inner face 14 of the bottom wall 4a.

The pads 27 of the circuit board 26 face the other ends of the signal wires 20. The pads 27 and the other ends of the signal wires 20 are electrically connected to each other via a rubber connector 31. The rubber connector 31 is sometimes called an “elastic connector”, and is interposed between the bottom wall 4a of the unit structure 4d and one end of the circuit board 26.

As illustrated in FIGS. 5 to 7, the rubber connector includes a connector body 32 and plural metal wires 33. The connector body 32 is formed by a rubber elastic body such as silicone rubber, for example, and has an elongated shape extended in a direction in which the connector body 32 traverses the other ends of the signal wires 20. Therefore, the connector body 32 has: a first end part 32a; and a second end part 32b located opposite to the first end part 32a. The first and second end parts 32a and 32b are located away from each other in a longitudinal direction of the connector body 32.

The metal wires 33 are exemplified as conductors and are integrally embedded in the connector body 32 so as to be passed through the connector body 32 in its thickness direction. Moreover, the metal wires 33 are arranged in a row at intervals in the longitudinal direction of the connector body 32.

The connector body 32 is compressed in its thickness direction between the bottom wall 4a of the unit structure 4d and the circuit board 26. With this compression, one ends of the metal wires 33 are brought into contact with the signal wires 20, and the other ends of the metal wires 33 are brought into contact with the pads 27. Hence, the other ends of the signal wires 20 and the pads 27 are electrically connected to each other via the metal wires 33.

As illustrated in FIGS. 2 and 5, the inner face 14 of the bottom wall 4a of the unit structure 4d is integrally provided with a holder part 35 for determining an attachment position of the rubber connector 31 with respect to the unit structure 4d. The holder part 35 according to the present embodiment has a first engagement part 36 and a second engagement part 37.

The first engagement part 36 has a rib shape protruded upward from the inner face 14 of the bottom wall 4a, and surrounds the first end part 32a of the connector body 32 from three directions, thereby restraining the first end part 32a. Similarly, the second engagement part 37 has a rib shape protruded upward from the inner face 14 of the bottom wall 4a, and surrounds the second end part 32b of the connector body 32 from three directions, thereby restraining the second end part 32b. Therefore, the first and second engagement parts 36 and are located away from each other in the longitudinal direction of the connector body 32.

The connector body 32 is held by the holder part 35 so that the connector body 32 runs between the first and second engagement parts 36 and 37. Thus, the positioning of the connector body 32 is determined along the width direction and depth direction of the housing 4.

Moreover, the first and second engagement parts 36 and 37 are located between the boss parts 28a and 28b to which the circuit board 26 is fixed. A height dimension H1 of each of the first and second engagement parts 36 and 37 is equal to a height dimension H2 of each of the boss parts 28a and 28b. Thus, with the circuit board 26 fixed to the boss parts 28a and 28b, upper ends of the first and second engagement parts 36 and 37 abut against the lower face of the circuit board 26, and receive the circuit board 26 from the direction of the bottom wall 4a.

As illustrated in FIG. 7, the height dimension H1 of each of the first and second engagement parts 36 and 37 is set to be smaller than a thickness dimension H3 of the connector body 32, which is measured when the connector body 32 is in a free state before being compressed. Therefore, as illustrated in FIG. 2, in a state where the circuit board 26 is yet to be fixed to the boss parts 28a and 28b, an upper end portion of the connector body 32 is projected upward from the upper ends of the first and second engagement parts 36 and 37.

Next, the procedure for establishing connections between the signal wires 20 printed on the bottom wall 4a of the unit structure 4d and the pads 27 of the printed circuit board 25 by using the rubber connector 31 will be described.

First, the first end part 32a of the connector body 32 is fitted into the first engagement part 36 of the holder part 35, and the second end part 32b of the connector body 32 is fitted into the second engagement part 37 of the holder part 35. Thus, the position of the rubber connector 31 is determined with respect to the bottom wall 4a of the unit structure 4d. With the positioning of the rubber connector 31 determined, the upper end portion of the connector body 32 is projected upward from the first and second engagement parts 36 and 37 as illustrated in FIGS. 2 and 7.

Subsequently, the printed circuit board 25 is fixed via the screws 29 to upper ends of the boss parts 28a and 28b protruded from the bottom wall 4a. With this fixation, the circuit board 26 of the printed circuit board 25 is brought into contact with the upper end portion of the connector body 32, thus pressing the connector body 32 toward the bottom wall 4a of the unit structure 4d.

As a result, the connector body 32 is compressed in its thickness direction between the bottom wall 4a and the circuit board 26. Moreover, the lower face of the circuit board 26 abuts against the upper ends of the first and second engagement parts 36 and 37 of the holder part 35, and the circuit board 26 is received by the first and second engagement parts 36 and 37 from below.

Thus, a distance between the circuit board 26 and the bottom wall 4a is determined, and an amount of compression of the connector body 32 is regulated. In other words, the first and second engagement parts 36 and 37 of the holder part 35 determine the position of the connector body 32 with respect to the bottom wall 4a of the housing 4, and concurrently restrict excessive compression of the connector body 32.

Upon compression of the connector body 32 between the circuit board 26 and the bottom wall 4a, one ends of the metal wires 33 are brought into contact with the signal wires 20 at an appropriate pressure. Similarly, the other ends of the metal wires 33 are brought into contact with the pads 27 of the printed circuit board 25 at an appropriate pressure. Hence, a state where the signal wires 20 of the housing 4 and the printed circuit board 25 are electrically connected to each other via the rubber connector 31 is maintained.

According to the above-described embodiment, the housing 4 is partially formed so as to be attachable and detachable as the unit structure 4d, thus making it possible to replace only a part of the housing 4, which is provided with a wiring structure. For example, when a faulty connection has occurred in wiring at a region where the connector 10 is mounted, the unit structure 4d is detached from the housing 4 and replaced, thereby enabling repair and enhancing maintainability of the electronic apparatus.

Furthermore, the housing 4 is partially formed so as to be attachable and detachable as the unit structure 4d, thus reducing expansion of deformation caused in the housing 4. Besides, a part of the housing 4, to which the conductive adhesives 23 are applied, is reduced in size as the unit structure 4d, thereby enhancing productivity in batch processing such as thermal hardening of the conductive adhesives 23. Specifically, when the conductive adhesives 23 are heated and hardened in a furnace or the like, production efficiency can be increased by size reduction resulting from unitization.

While the unit structure 4d formed by the bottom wall 4a and the lateral wall 4c is exemplified, the embodiment is not limited to this structure. For example, the unit structure 4d may be formed only by the bottom wall 4a. In other words, the lateral wall 4C may be formed as an integral unit, and an attachable and detachable part thereof may be eliminated.

The present invention is not limited to the foregoing embodiment as it is, but may be implemented by making modifications to constituent elements without departing from the scope of the present invention. Various inventions may be provided by an appropriate combination of plural constituent elements disclosed in the foregoing embodiment. For example, several constituent elements may be eliminated from the entire constituent elements disclosed in the embodiment. Moreover, the constituent elements in different embodiments may be combined as appropriate.

What is claimed is:

1. An electronic apparatus, comprising:
an electrically-insulative housing having
a first part and
a second part attachable to and detachable from the first part;
a circuit board housed in the housing;
a signal wire formed on an inner face of the second part; and
a connector formed to electrically connect the signal wire and a terminal part of the circuit board.

2. The apparatus of claim 1,
wherein the second part has an opening formed to expose the connector.

3. The apparatus of claim 1,
wherein the second part has:
a lateral wall portion having an opening formed to expose the connector; and
a bottom wall portion on which the signal wire is formed.

4. The apparatus of claim 1,
wherein the signal wire is formed of a conductive adhesive printed on the inner face of the second part so as to be integral with the second part.

5. An electronic apparatus, comprising:
an electrically-insulative housing;
a circuit board housed in the housing;
a connector formed to connect with another device; and
a signal wire formed to electrically connect a connection terminal of the connector and a terminal part of the circuit board,
wherein the housing is separable into a first part and a second part, the second part being smaller than the first part, and
wherein the signal wire is provided on the inner face of the second part.
